(19) United States
(12) Patent Application Publication
(10) Pub. No.: US 2003/0156399 A1
(43) Pub. Date: Aug. 21, 2003

(54) Integrated bulkhead handle assembly

(76) Inventors: Sean A. Cerniglia, Cool, CA (US); Michael L. Wortman, Sacramento, CA (US)

Correspondence Address: HEWLETT-PACKARD COMPANY, Intellectual Property Administration, P.O. Box 272400, Fort Collins, CO, 80527-2400, US

(21) Appl. No.: 10/077,826

(22) Filed: Feb. 15, 2002

(51) Int. Cl. H05K 7/14; H05K 7/18

(52) U.S. Cl. 361/802

(57) ABSTRACT

An integrated bulkhead handle assembly for reducing misalignment of a substrate coupled with a bulkhead is disclosed. In one embodiment, the present invention is comprised of a handle element adapted to be removably coupled with a bulkhead. The present embodiment is further comprised of a retaining element fixedly coupled with the handle element. Beneficially, the retaining element is adapted too removably couple a substrate such that misalignment of the substrate with respect to the bulkhead is reduced.

### TECHNICAL FIELD

The present claimed invention relates to the field of chassis structures. More specifically, the present claimed invention relates to integrated bulkhead handles employed in conjunction with computer chassis structures.

### BACKGROUND ART

A compact peripheral component interconnect (PCI) is a smaller version of a PCI. In general, a compact PCI is half the size of a regular PCI, thus allowing two compact PCIs to be stacked into a normal PCI slot. Presently, compact PCI assemblies include a printed circuit assembly (PCA) (for example, a PC board with associated microcircuits), a bulkhead, and top and bottom pull handles. Normally, the PCA attaches to one side of the bulkhead and the handles attach to the other. The assembled compact PCI is then attached to a chassis. Typically, compact PCI attaching standards include, for example, the compact peripheral component interconnect (CPCI) standard, and the VersaModular Eurocard (VME) standard.

The problems with assembling a compact PCI are trifold. The first problem is the skill level required for assembly. In general, a few complex steps are required to assemble a compact PCI. The complexities include the number of distinct parts, the small size of each distinct part, and the risk of putting the small parts together incorrectly. For example, a miss-aligned component may cause a PCA to be mounted incorrectly. In fact, a PCA may be pushed in an outward direction with respect to the bulkhead. In such a condition, the PCA could detrimentally effect the entire system. For example, the detrimental effects may include a short between PCAs or associated microcircuits, misalignment of connector pins, and in extreme cases a broken PCA or chassis.

The second problem with a compact PCI is the assembly cost. Generally speaking, each piece required for the compact PCI assembly has an associated per item cost. A further cost is accrued due to the above stated complexities associated with present assembly techniques. That is, the more complex the assembly operation the more time and skill required in order to complete the assembly process. The increase in time requirements translates into accrued cost. Additionally, increased skill factors normally result in higher pay to an employee or greater cost associated with higher performance machinery.

A third problem with a compact PCI is attachment to the computer chassis. Normally, attachment is done with the use of captive screws. The captive screws are disposed on the traditional compact PCI at locations corresponding to mounting holes residing within the computer chassis. The location and the spacing of mounting holes within the computer chassis (and the corresponding location of the captive screws on the traditional compact PCI) are often defined by an industry standard.

To reiterate, typical standards include, for example, the compact peripheral component interconnect (CPCI) standard, and the VersaModular Eurocard (VME) standard. For example, the CPCI standard dictates that the gap between adjacent units (e.g. adjacent compact PCIs) should be nominally set at 0.30 millimeters. Unfortunately, industry-standard captive screws allow a traditional compact PCI to be mispositioned by more than 1.0 millimeter. For purposes of the present application, this mispositioning with respect to the computer chassis, caused in some cases by the use of captive screws, is referred to as interference generating movement. During use, the interference generating movement of one compact PCI can deleteriously prevent insertion of a second compact PCI. That is, interference generating movement of one or more compact PCIs can result in insufficient space in a neighboring slot such that another compact PCI will not fit in the compromised gap.

At present, one approach to fix the problem described above is to first have all of the necessary compact PCIs and any required filler panels loosely connected to the computer chassis. Once all of the compact PCIs are in place, they are then carefully tightened to the computer chassis in order to insure that interference generating movement is reduced as much as possible. However, such a method is time-consuming, cumbersome, and lacks the desired “Design for Manufacturability.”

### DISCLOSURE OF THE INVENTION

The present invention provides an integrated bulkhead handle method and apparatus which reduces misalignment of a substrate with respect to a bulkhead. The present invention also provides an integrated bulkhead handle method and apparatus which achieves the above accomplishment and which facilitates monetary savings. The present invention also provides an integrated bulkhead handle method and apparatus which achieves the above accomplishments and which can be adapted to readily interface with industry standard components and meet industry standard specifications.

Specifically, an integrated bulkhead handle assembly for reducing misalignment of a substrate coupled with a bulkhead is disclosed. In one embodiment, the present invention is comprised of a handle element adapted to be removably coupled with a bulkhead. The present embodiment is further comprised of a retaining element fixedly coupled with the handle element. Beneficially, the retaining element is adapted too removably couple a substrate such that misalignment of the substrate with respect to the bulkhead is reduced.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1A is a side view of an integrated bulkhead handle assembly in accordance with one embodiment of the present claimed invention.

FIG. 1B is a rear view of an integrated bulkhead handle assembly in accordance with one embodiment of the present claimed invention.

FIG. 1C is a front view of an integrated bulkhead handle assembly in accordance with one embodiment of the present claimed invention.

FIG. 2 is a side view of an integrated bulkhead handle assembly coupled with a bulkhead in accordance with one embodiment of the present claimed invention.

FIG. 3 is a side view of an integrated bulkhead handle assembly coupled with a bulkhead and a substrate to reduce misalignment of the substrate with respect to the bulkhead in accordance with one embodiment of the present claimed invention.

FIG. 4 is a flow chart of steps performed in accordance with one embodiment of the present claimed invention.

The drawings referred to in this description should be understood as not being drawn to scale except if specifically noted.

### BEST MODES FOR CARRYING OUT THE INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail as not to unnecessarily obscure aspects of the present invention.

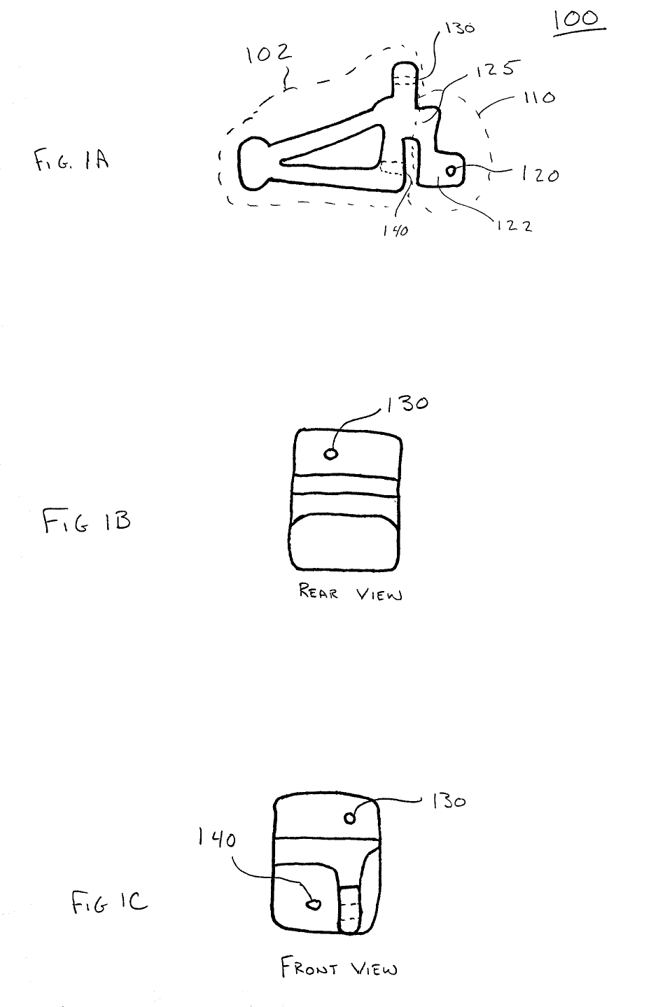

With reference now to FIGS. 1A-1C, side, rear, and front views of an integrated bulkhead handle assembly 100 in accordance with one embodiment of the present claimed invention are shown. The following discussion will begin with a detailed description of the physical characteristics of the present integrated bulkhead handle assembly 100. The discussion will then contain a detailed description of the use and operation of the present integrated bulkhead handle assembly 100. Referring now to the physical characteristics of the present integrated bulkhead handle assembly 100, in the present embodiment, integrated bulkhead handle assembly 100 includes handle element 102 and retaining element 110. As discussed in detail herein, in one embodiment, handle element 102 includes bulkhead-attaching device 140, and chassis-attaching device 130. Additionally, retaining element 110 includes substrate-attaching device 120.

With reference now to FIG. 1A, as stated above, integrated bulkhead handle assembly 100 includes handle element 102 and retaining element 110. Specifically, retaining element 110 is integrated with handle element 102. For example, retaining element 110 is extruded from handle element 102. Although an extrusion is stated in the present embodiment integrated bulkhead handle assembly 100 may be formed utilizing processes such as “shaping”, “casting”, “molding”, “machining”, “milling”, “welding”, “sculpting”, “compressing” or the like.

Referring still to FIG. 1A, in one embodiment, substrate-attaching device 120 is comprised of a screw. Substrate-attaching device 120 is ultimately employed to removably couple retaining portion 110 to a substrate. In one embodiment, the substrate is a printed circuit board (PCB). Additionally, substrate-attaching device 120 is an attaching device formed having dimensions and characteristics which are in compliance with an industry standard such as, for example, the CPCI standard, and the VME standard. Also, although a screw is specifically mentioned as the substrate-attaching device 120 in the present embodiment, the present invention is also well suited to use with various other types of attaching devices including, for example, D-clips, snaps, and the like.

With reference now to FIG. 1B, a rear view of an integrated bulkhead handle assembly 100 is shown. Specifically, chassis-attaching device 130 is shown in one configuration on handle element 102. In one embodiment, chassis-attaching device 130 is comprised of a captive screw. Chassis-attaching device 130 is ultimately employed to removably couple handle element 102 to a computer chassis. Additionally, chassis-attaching device 130 is an attaching device formed having dimensions and characteristics which are in compliance with an industry standard such as, for example, the CPCI standard, and the VersaModular Eurocard (VME) standard. Also, although a captive screw is specifically mentioned as the chassis-attaching device 130 in the present embodiment, the present invention is also well suited to use with various other types of attaching devices including, for example, D-clips, snaps, and the like.

With reference now to FIG. 1C, a front view of an integrated bulkhead handle assembly 100 is shown. Specifically, bulkhead-attaching device 140 is shown in one configuration on handle element 102. Additionally, bulkhead-attaching device 140 is comprised of a screw. Bulkhead-attaching device 140 is ultimately employed to removably couple integrated bulkhead handle 100 to a bulkhead, such as, a CPCI or VME standard bulkhead. Although a screw is specifically mentioned as the bulkhead attaching device 140, the present invention is also well suited to use with various other types of attaching devices including, for example, D-clips, snaps, and the like.

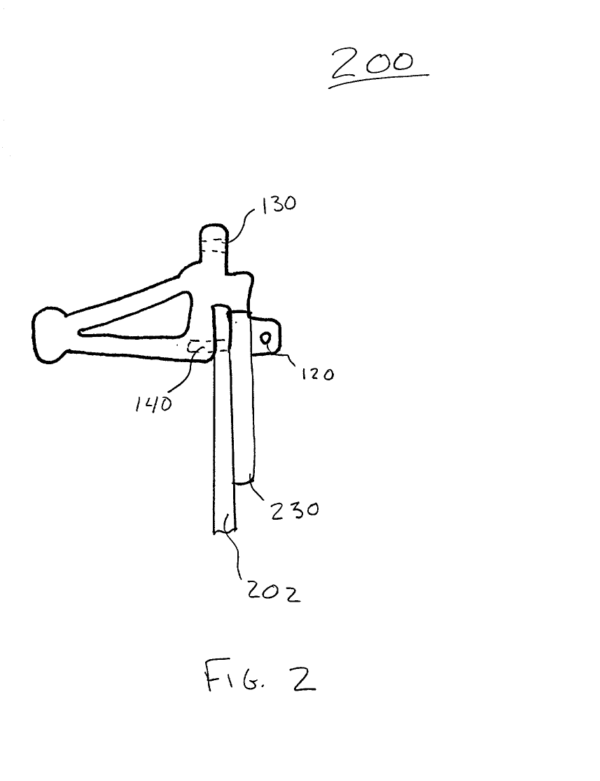

Referring now to FIG. 2, integrated bulkhead handle assembly 100 is coupled with a bulkhead 202. In general, integrated bulkhead handle assembly 100 attaches to bulkhead 202 with a tight fit that further squares retaining portion 110 with bulkhead 202. Further details with respect to the orientation of integrated bulkhead handle assembly 100 are described below. Regarding the physical structure of bulkhead 202, for purposes of clarity, only a portion of a bulkhead 202 is shown in FIG. 2. In addition, it is appreciated that embodiments of bulkhead 202 may include a PCI bulkhead, a CPCI bulkhead, a VME standard bulkhead, or any other type of bulkhead that may be coupled with a chassis. The use of a CPCI bulkhead in the present embodiment is for purposes of brevity and clarity.

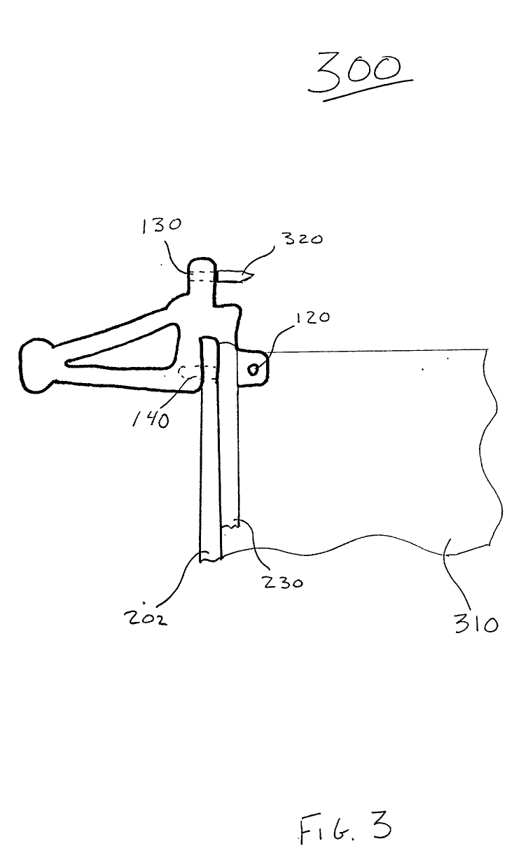

Referring now to FIG. 3, integrated bulkhead handle assembly 100 is coupled with a substrate 310. That is, integrated bulkhead handle assembly 100 is removably coupled with bulkhead 202 and then substrate 310 is removably coupled with integrated bulkhead handle assembly 100. As stated above, due to the design standards of integrated bulkhead handle assembly 100, the resulting assembly 300 includes substrate 310 which is squared with respect to bulkhead 202. Regarding the physical structure of substrate 310, for purposes of clarity, only a portion of a substrate 310 is shown in FIG. 2. In addition, it is appreciated that embodiments of substrate 310 may be defined by PCI, CPCI, or VME sizing standard, or any other type of substrate standard that may be coupled with a chassis. The use of a PCB as the substrate in the present embodiment is merely for purposes of clarity.

With reference still to FIG. 3, in one embodiment integrated bulkhead handle assembly 100 of the present invention also includes a locating element 320 which is coupled with handle element 102. Locating element 320 is adapted to be inserted in an opening (e.g. a mounting hole) in a computer chassis to reduce interference generating movement. Specifically, locating element 320 is adapted to orient bulkhead 202 with respect to a computer chassis such that interference generating movement of bulkhead 202 is reduced.

### USE AND OPERATION

The following is a detailed description of the use and operation of the present integrated bulkhead handle assembly 100. With reference to FIGS. 1A-3, one embodiment of an integrated bulkhead handle assembly 100 is shown. Generally speaking, integrated bulkhead handle assembly 100 is an assembly for attaching an integrated handle assembly 100 and a substrate (e.g. PCB 310) to a bulkhead (such as a CPCI bulkhead 202). The resulting assembly (e.g. assembly 300) is a complete one-piece printed circuit assembly (PCA) designed for simple insertion with, and removal from, a computer chassis.

With reference now to FIGS. 1A-1C, handle element 102 is adapted to be removably coupled with a bulkhead. In general, handle element 102 is designed with a dimensional fit and isolated to a single tolerance. As such, handle element 102 maintains a consistent and robust design for manufacturability. Specifically, handle element 102 is an industrial design consistent with CPCI and VME standards. Although in the present embodiment, handle element 102 is shown with a triangular shape, handle element 102 may be any type of projection which affords a grasping surface.

With reference still to FIGS. 1A-C, in one embodiment of the present invention, retaining element 110 is integral with a handle such as handle element 102. In one embodiment, retaining element 110 is fixedly coupled with handle element 102 proximate to the location where substrate 310 is, or will be, disposed. In the present embodiment, retaining element 110 rigidly extends from handle element 102 and does not shift in position with respect to handle element 102.

Generally speaking, retaining element 110 is designed with two main criteria. The first is the mounting criterion. Specifically, retaining element 110 has a mounting portion 122 adapted too removably couple a substrate 310 (such as a PCB). In general, mounting portion 122 includes the substrate attaching device 120 previously described herein. Furthermore, mounting portion 122 is aligned perpendicular to the bulkhead 202 of FIG. 2. Thus, substrate 310 is mounted in a perpendicular orientation (i.e. square) with reference to bulkhead 202.

The second criterion of retaining element 110 is an aligning criterion. Specifically, retaining element has an aligning portion 125 integrated with mounting portion 122. In general, aligning portion 125 is adapted to orient substrate 310 with respect to bulkhead 202 to reduce alignment errors of substrate 310 with respect to bulkhead 202. That is, any misalignment errors of the complete assembly 300 will be minimal. Accordingly, the chances of misalignment when assembly 300 is inserted into a computer chassis are greatly reduced. Therefore, the possibility of substrate 310, or any microcircuit devices thereon, unintentionally contacting another PCA are reduced. In addition, further detrimental effects such as a misalignment of connector pins, or in extreme cases a broken PCA or chassis are also reduced.

With reference now to FIG. 2, the present invention is well suited to attaching the integrated bulkhead handle assembly 100 to a bulkhead 202 without requiring remanufacturing, retooling, or redesigning of bulkhead 202. Hence, integrated bulkhead handle assembly 100 does not limit customers to one particular design/maker of bulkheads. Instead, it allows customers to realize the beneficial reduced misalignment of a substrate 310 coupled with a bulkhead 202 while still utilizing the particular bulkhead of the customer's choice. As one example, integrated bulkhead handle assembly 100 is well suited to use with various types of bulkheads 202 having EMI shield portions 230 which are removably coupled thereto, and also bulkheads 202 having EMI shield portions 230 which are integral therewith. As another example, integrated bulkhead handle assembly 100 is well suited to use with various types of bulkheads having various types of attaching devices.

With reference now to FIG. 3, the present invention is well suited to attaching the integrated bulkhead handle assembly 100 to a substrate 310 without requiring remanufacturing, retooling, or redesigning of substrate 310. Hence, integrated bulkhead handle assembly 100 does not limit customers to one particular design/maker of substrate 310. Instead, it allows customers to realize the beneficial reduced misalignment of a substrate 310 coupled with a bulkhead 202 while still utilizing the particular substrate 310 of the customer's choice. As one example, integrated bulkhead handle assembly 100 is well suited to use with various types of substrates 310 having any type of printed circuit assemblies' integral therewith. As another example, integrated bulkhead handle assembly 100 is well suited to use with various types of substrates having various dimensions as required by VME and CPCI specifications for PCBs.

Referring still to FIG. 3, in one embodiment of the present invention, locating element 320 is coupled to integrated bulkhead handle assembly 100 at a location such that the insertion portion of locating element 320 will correspond to mounting holes disposed on a computer chassis. That is, in one such embodiment, locating element 320 is rigidly coupled to integrated bulkhead handle assembly 100 at a location such that locating element 320 will subsequently engage an opening in a computer chassis and, in so doing, firmly retain integrated bulkhead handle assembly 100 at a desired orientation with respect to the computer chassis. As a result, subsequent to the insertion of locating element 320 into an opening in computer chassis, the present invention allows chassis attaching device 130 to be coupled to the computer chassis without concern for deleterious interference generating movement.

Furthermore, in one embodiment of the present invention, locating element 320 is coupled to integrated bulkhead handle assembly 100 at a location which corresponds to an industry standard such as, for example, the compact peripheral component interconnect (CPCI) standard or the VersaModular Eurocard (VME) standard. In such an embodiment, locating element 320 will subsequently engage an opening (e.g. a mounting hole) in a computer chassis and, in so doing, firmly retain integrated bulkhead handle assembly 100 at an orientation such that the nominal spacing specified by the standard between an adjacent device (e.g. another filler panel or a PCA) is obtained.

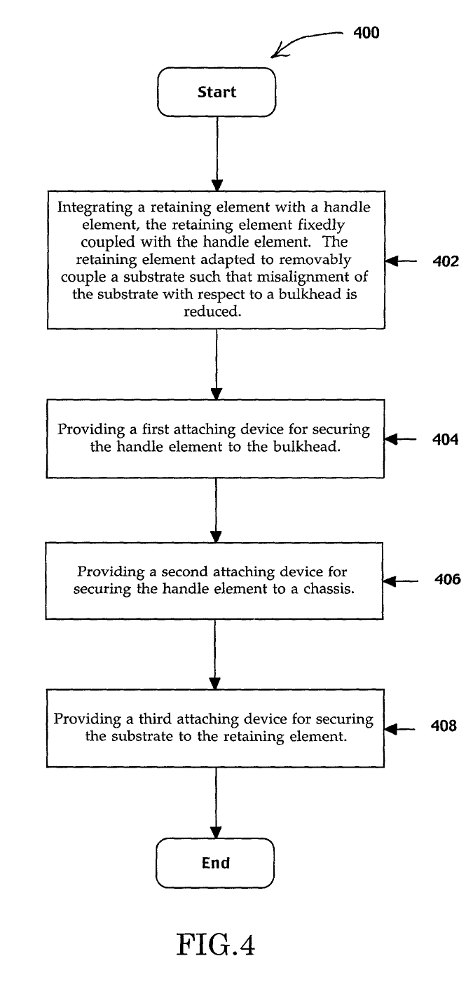

With reference now to FIG. 4, a flow chart 400 summarizing the steps performed in accordance with one embodiment of the present invention is shown. At step 402, the present embodiment integrates a retaining element 110 with a handle element 102. Specifically, retaining element 110 is fixedly coupled with handle element 102. As described in detail above, retaining element 110 is adapted to removably couple a substrate 310 such that misalignment of substrate 310 with respect to a bulkhead 202 is reduced.

Next, at step 404, the present embodiment provides a first attaching device (e.g. bulkhead-attaching device 140) for securing handle element 102 to bulkhead 202. At step 406, the present embodiment provides a second attaching device (e.g. chassis-attaching device 130) for securing handle element 102 to a computer chassis. Next at step 408, the present embodiment provides a third attaching device (e.g. substrate-attaching device 120) for securing substrate 310 to retaining element 110. Beneficially, the present embodiment reduces the possibility of a misaligned substrate 310 (e.g. a PCB) with respect to bulkhead 202. As a result, the possibility for alignment problems when inserting assembly 300 into a chassis is also reduced. In addition, the present embodiment allows simplified attachment of a substrate 310 to a bulkhead 202 via integrated bulkhead handle assembly 100. Thus, the present invention achieves a “Design for Manufacturability” lacking in the prior art. Additionally, by reducing the number of parts and the technical labor requirements, the present embodiment provides a more efficient, less expensive integrated bulkhead handle assembly 100.

Thus, the present invention provides an integrated bulkhead handle method and apparatus which reduces misalignment of a substrate with respect to a bulkhead. The present invention also provides an integrated bulkhead handle method and apparatus which achieves the above accomplishment and which facilitates monetary savings. The present invention also provides an integrated bulkhead handle method and apparatus which achieves the above accomplishments and which can be adapted to readily interface with industry standard components and meet industry standard specifications.

The foregoing descriptions of specific embodiments of the present invention have been presented for purposes of illustration and description. They are not intended to be exhaustive or to limit the invention to the precise forms disclosed, and modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

1. An integrated bulkhead handle assembly comprising:
a handle element adapted to be removably coupled with a bulkhead; and
a retaining element integral with said handle element, said retaining element fixedly coupled with said handle element, said retaining element adapted to removably couple a substrate such that misalignment of said substrate with respect to said bulkhead is reduced.

2. The integrated bulkhead handle assembly of claim 1, wherein said retaining element is extruded from said handle element.

3. The integrated bulkhead handle assembly of claim 1, wherein said bulkhead is a compact peripheral component interconnect (CPCI) bulkhead.

4. The integrated bulkhead handle assembly of claim 1, wherein said substrate is a printed circuit board (PCB).

5. The integrated bulkhead handle assembly of claim 1 further comprising:
a first attaching device coupled with said handle element, said first attaching device for removably coupling said handle element with said bulkhead.

6. The integrated bulkhead handle assembly of claim 1 further comprising:
a second attaching device coupled with said handle element, said second attaching device for removably coupling said handle element with a chassis.

7. The integrated bulkhead handle assembly of claim 1 further comprising:
a third attaching device coupled with said retaining element, said third attaching device for removably coupling said substrate with said retaining element.

8. The integrated bulkhead handle assembly of claim 1 wherein said retaining element is comprised of:
a mounting portion adapted to removably couple a substrate; and
an aligning portion integrated with said mounting portion, said aligning portion adapted to orient said substrate with respect to said bulkhead to reduce alignment errors of said removably coupled substrate with respect to said bulkhead.

9. The integrated bulkhead handle assembly of claim 8 wherein said retaining element is integrated with said handle element such that said mounting portion is perpendicular to said bulkhead.

10. The integrated bulkhead handle assembly of claim 8 wherein said retaining element is integrated with said handle element such that said aligning portion is parallel with said bulkhead.

11. The integrated bulkhead handle assembly of claim 1 wherein said handle element further comprises a locating element coupled to said handle element, said locating element adapted to orient said bulkhead with respect to a chassis such that interference generating movement of said bulkhead is reduced.

12. A method for using a bulkhead handle to reduce misalignment of a substrate coupled with a bulkhead comprising:
a) integrating a retaining element with a handle element, said retaining element fixedly coupled with said handle element, said retaining element adapted to removably couple a substrate such that misalignment of said substrate with respect to a bulkhead is reduced;
b) providing a first attaching device for securing said handle element to said bulkhead;
c) providing a second attaching device for securing said handle element to a chassis; and
d) providing a third attaching device for securing said substrate to said retaining element.

13. The method for using a bulkhead handle to reduce misalignment of a substrate coupled with a bulkhead as recited in claim 12 wherein said step a) further comprises extruding said retaining element from said handle element.

14. The method for using a bulkhead handle to reduce misalignment of a substrate coupled with a bulkhead as recited in claim 12 wherein said bulkhead is a compact peripheral component interconnect (CPCI) bulkhead.

15. The method for using a bulkhead handle to reduce misalignment of a substrate coupled with a bulkhead as recited in claim 12 wherein said substrate is a printed circuit board (PCB).

16. The method for using a bulkhead handle to reduce misalignment of a substrate coupled with a bulkhead as recited in claim 12 wherein said step a) further comprises extruding said retaining element having a mounting portion and an alignment portion integrated with said mounting portion.

17. The method for using a bulkhead handle to reduce misalignment of a substrate coupled with a bulkhead as recited in claim 12 wherein said step a) further comprises aligning said retaining element such that said mounting portion is perpendicular to said bulkhead.

18. The method for using a bulkhead handle to reduce misalignment of a substrate coupled with a bulkhead as recited in claim 12 wherein said step a) further comprises aligning said retaining element such that said aligning portion is parallel with said bulkhead.

19. The method for using a bulkhead handle to reduce misalignment of a substrate coupled with a bulkhead as recited in claim 12 wherein said step a) further comprises coupling a locating element to said handle element, said locating element adapted to orient said PCI bulkhead with respect to a chassis such that interference generating movement of said bulkhead is reduced.

20. The method for using a bulkhead handle to reduce misalignment of a substrate coupled with a bulkhead as recited in claim 12 wherein said step c) further comprises utilizing said second attaching device to removably couple said handle element with a chassis in accordance with the group consisting of compact peripheral component interconnect (CPCI) standard and VersaModular Eurocard (VME) standard.

21. An integrated PCI bulkhead handle assembly comprising:
a handle element adapted to be removably coupled with a PCI bulkhead; and
a retaining element integral with said handle element, said retaining element fixedly coupled with said handle element, said retaining element adapted to removably couple a PC board with respect to a PCI bulkhead such that misalignment of said PC board with respect to said PCI bulkhead is reduced said retaining element comprised of:
a mounting portion adapted to removably couple a PC board; and
an aligning portion integrated with said mounting portion, said aligning portion adapted to orient said PC board with respect to said PCI bulkhead to reduce alignment errors of said removably coupled PC board with respect to said PCI bulkhead; and

22. The integrated PCI bulkhead handle assembly of claim 21, wherein said retaining element is extruded from said handle element.

23. The integrated PCI bulkhead handle assembly of claim 21 wherein said retaining element is coupled with said handle element such that said mounting portion is perpendicular to said PCI bulkhead.

24. The integrated PCI bulkhead handle assembly of claim 21 wherein said retaining element is coupled with said handle element such that said aligning portion is parallel with said PCI bulkhead.

25. The integrated PCI bulkhead handle assembly of claim 21 wherein said handle element further comprises a locating element coupled to said handle element, said locating element adapted to orient said PCI bulkhead with respect to a chassis such that interference generating movement of said PCI bulkhead is reduced.
